(19) United States
(12) Patent Application Publication
(10) Pub. No.: US 2026/0088782 A1
(43) Pub. Date: Mar. 26, 2026

(54) POWER DEVICE WITH FAST RESPONSE TO PULSED RF SIGNAL

(71) Applicant: SKYWORKS SOLUTIONS, INC., Irvine, CA (US)

(72) Inventors: Yu Zhu, Wellesley, MA (US); Alan John Harrison, Manotick (CA); Oleksiy Klimashov, Burlington, MA (US); Paul T. DiCarlo, Marlborough, MA (US)

(21) Appl. No.: 19/213,344

(22) Filed: May 20, 2025

Related U.S. Application Data
(60) Provisional application No. 63/649,975, filed on May 21, 2024.

(51) Int. Cl. H03F 3/24; H04B 1/40

(52) U.S. Cl. CPC H03F 3/245; H04B 1/40; H03F 2200/451

(57) ABSTRACT

Aspects of the present disclosure are directed to a power amplifier and a bias circuit. The power amplifier includes an input port configured to receive an input radio frequency (RF) signal, an output port configured to output an amplified RF signal, one or more amplification stages implemented between the input port and the output port, the one or more amplification stages configured to amplify the input RF signal to yield the amplified RF signal, and one or more bias circuits. Each bias circuit includes a pre-charging circuit coupled to the input port and configured to generate a pre-charging bias signal for the one or more amplification stages, the pre-charging bias signal being active prior to the input RF signal for pre-heating the one or more amplification stages.

### CROSS-REFERENCE TO RELATED APPLICATIONS

This application claims priority under 35 U.S.C. § 119 (e) to U.S. Provisional Patent Application 63/649,975 titled JPOWER DEVICE WITH FAST RESPONSE TO PULSED RF SIGNAL, filed on May 21, 2024, and hereby incorporated by reference in its entirety for all purposes.

### BACKGROUND

### Technical Field

Aspects and embodiments of the present disclosure generally relate to power amplifiers (PAS) for radio frequency (RF) applications. In particular, the present disclosure relates to bias circuits for power amplifiers (PAS).

### Description of Related Technology

In radio frequency (RF) applications, an RF signal to be transmitted is typically generated by a transceiver. Such an RF signal can then be amplified by a power amplifier (PA), and the amplified RF signal can be routed to an antenna for transmission. Nevertheless, due to a self-heating and trapping effect, the response of a power device like the PA to a pulsed RF signal could be on the order of microseconds and even seconds.

### SUMMARY

The innovations described in the claims each have several aspects, no single one of which is solely responsible for its desirable attributes. Without limiting the scope of the claims, some prominent features of this disclosure will now be briefly described.

In a first aspect, a bias circuit for a power amplifier is disclosed. The bias circuit comprises a pre-charging circuit coupled to an input port of a power amplifier and configured to generate a pre-charging bias signal for one or more amplification stages. The pre-charging bias signal is active prior to a to-be-amplified radio frequency signal for pre-heating the one or more amplification stages.

In some embodiments, the pre-charging bias signal includes a pre-charging bias voltage.

In some embodiments, the pre-charging bias signal includes a pulsed signal.

In some embodiments, the pre-charging bias signal includes a pulsed DC signal.

In some embodiments, the pulsed DC signal has a junction temperature response with a heating gradient that corresponds to a junction temperature response of the to-be-amplified radio frequency signal.

In some embodiments, the pre-charging bias signal is active at least three microseconds prior to the to-be-amplified radio frequency signal.

In some embodiments, the pre-charging bias signal is active at least five microseconds prior to the to-be-amplified radio frequency signal.

In some embodiments, the pre-charging bias signal is activated at substantially a same time as the to-be-amplified radio frequency signal.

In some embodiments, a response signal has a drain current, the drain current having a gain variation of 0.10 or less. The gain variation can be defined as

$$Gain ( 1 us ) / Gain ( 1 ms ) = 20 log ( Id ( 1 us ) / Id ( 1 ms ) ) = 20 log ( 1 + deltaId / Id ) == 20 ( log e ) * deltaId / Id = 8.7 deltaId / Id .$$

In a second aspect, a power amplifier (PA) is disclosed. The power amplifier comprises an input port configured to receive an input radio frequency (RF) signal and an output port configured to yield an amplified RF signal. The power amplifier also comprises one or more amplification stages implemented between the input port and the output port. The one or more amplification stages configured to amplify the input RF signal to yield the amplified RF signal. Further, the power amplifier comprises one or more bias circuits, each bias circuit including a pre-charging circuit coupled to the input port. Furthermore, the pre-charging circuit is configured to generate a pre-charging bias signal for the one or more amplification stages. The pre-charging bias signal is active prior to the input RF signal for pre-heating the one or more amplification stages.

In some embodiments, the pre-charging bias signal includes a pre-charging bias voltage.

In some embodiments, the pre-charging bias signal includes a pulsed signal.

In some embodiments, the pre-charging bias signal includes a pulsed DC signal.

In some embodiments, the pulsed DC signal has a junction temperature response with a heating gradient that corresponds to a junction temperature response of the to-be-amplified radio frequency signal.

In some embodiments, the pre-charging bias signal is active at least three microseconds prior to the to-be-amplified radio frequency signal.

In some embodiments, the pre-charging bias signal is active at least five microseconds prior to the to-be-amplified radio frequency signal.

In some embodiments, the pre-charging bias signal is active at substantially a same time as the to-be-amplified radio frequency signal.

In some embodiments, a response signal has a drain current, the drain current having a gain variation of 0.10 or less.

In a third aspect, a wireless device is disclosed. The wireless device comprises a transceiver configured to generate a radio frequency (RF) signal, and an RF module in communication with the transceiver. The RF module includes a power amplifier (PA). The PA includes one or more amplification stages configured to amplify the RF signal. The PA further includes a bias circuit for each of the one or more amplification stages. The bias circuit includes a pre-charging circuit coupled to an input port of the PA and configured to generate a pre-charging bias signal for the one or more amplification stages. The pre-charging bias signal is active prior to the RF signal for pre-heating the one or more amplification stages. The wireless device also comprises an antenna in communication with the RF module, the antenna configured to facilitate transmission of the amplified RF signal.

In a fourth aspect, a method for operating a power amplifier (PA) is disclosed. The method comprises providing a bias circuit including a pre-charging circuit coupled to an input port of a power amplifier and configured to generate a pre-charging bias signal for one or more amplification stages. The method further comprises activating the pre-charging bias signal prior to a to-be-amplified radio frequency signal for pre-heating the one or more amplification stages.

In some embodiments, the pre-charging bias signal includes a pre-charging bias voltage.

In some embodiments, the pre-charging bias signal includes a pulsed signal.

In some embodiments, the pre-charging bias signal includes a pulsed DC signal.

In some embodiments, the pre-charging bias signal is activated at least three microseconds prior to the to-be-amplified radio frequency signal.

In some embodiments, the pre-charging bias signal is activated at least five microseconds prior to the to-be-amplified radio frequency signal.

In some embodiments, the pre-charging bias signal is deactivated when the to-be-amplified radio frequency signal is activated.

In some embodiments, the pre-charging bias signal is activated at the same time as the to-be-amplified radio frequency signal for accelerating a heating up of the one or more amplification stages.

In some embodiments, the pre-charging bias signal is deactivated one microsecond after the to-be-amplified radio frequency signal is activated.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 depicts a power amplifier (PA) having one or more amplification stages configured to receive an input signal and amplify it to generate an amplified signal, according to one embodiment of the present disclosure.

FIG. 2 shows an example of a peak voltage limiting (PVL) circuit implemented for a PA system having three amplification stages, according to one embodiment of the present disclosure.

FIG. 3 shows a plot comparing a measured drain current to a simulated drain current in response to the same initiating signal, according to one embodiment of the present disclosure.

FIG. 4 shows a plot of a drain voltage response and a drain current response to a pulsed DC signal, according to one embodiment of the present disclosure.

FIG. 5 shows a plot of a junction temperature response to the pulsed DC signal of FIG. 4.

FIG. 6 shows a plot of a drain current response to a pulsed RF signal, according to one embodiment of the present disclosure.

FIG. 7 shows a plot of a junction temperature response to the pulsed RF signal of FIG. 6.

FIG. 8 shows a gain variation plot of a drain current response.

FIG. 9 schematically depicts a pre-charging bias signal in relation to a to-be-amplified radio frequency signal, according to one embodiment of the present disclosure.

FIG. 10 shows a plot of a DC component response comparing a drain current with a pre-charging bias signal and without the pre-charging bias signal, according to one embodiment of the present disclosure.

FIG. 11 shows a plot of a junction temperature response to a pulsed DC signal and to a pulsed RF signal, according to one embodiment of the present disclosure.

FIG. 12 shows a plot of a junction temperature response with respect to the DC component response of FIG. 10.

FIG. 13 shows a gain variation plot of a fundamental drain current response, according to one embodiment of the present disclosure.

FIG. 14 shows a plot of a junction temperature response when a pre-charging bias signal has an increased amplitude, according to one embodiment of the present disclosure.

FIG. 15 shows a plot of a fundamental drain current with respect to the junction temperature response of FIG. 14.

FIG. 16 shows a plot of a junction temperature response comparing pre-charging bias signals having different amplitudes, according to one embodiment of the present disclosure.

FIG. 17 shows a plot of a fundamental drain current with respect to the junction temperature response of FIG. 16.

FIG. 18 schematically depicts a pre-charging bias signal in relation to a to-be-amplified radio frequency signal wherein the pre-charging bias signal is activated when the to-be-amplified radio frequency signal is activated, according to one embodiment of the present disclosure.

FIG. 19 shows a plot of a junction temperature response to a pulsed DC signal and to a pulsed RF signal when active at the same time as illustrated in FIG. 18.

FIG. 20 shows a gain variation plot of a fundamental drain current response to the pre-charging bias signal of FIG. 18.

FIG. 21 depicts a die 200 that can include a PVL circuit 104 having one or more features as described herein, according to one embodiment of the present disclosure.

FIG. 22 schematically depicts an example module having a packaging substrate that is configured to receive a plurality of components, according to one embodiment of the present disclosure.

FIG. 23 schematically depicts an example wireless device 400 having one or more advantageous features described herein, according to one embodiment of the present disclosure.

### DETAILED DESCRIPTION

The following detailed description of certain embodiments presents various description of specific embodiments. However, the innovation described herein can be embodied in a multiple of different ways, for example, as defined and covered by the claims. In this description, reference is made to the drawings where like reference numbers can indicate identical or functionally similar elements. It will be understood that elements illustrated in the figures are not necessarily drawn to scale. Moreover, it will be understood that certain embodiments can include more elements than illustrated in a drawing and/or in a subset of the elements illustrated in a drawing. Further, some embodiments can incorporate any suitable combination of features from two or more drawings.

Reducing effects of self-heating in power semiconductor devices may be accomplished using different approaches, such as process improvement based approaches, and circuit based approaches, for example. Process improvement is usually a long term project and has its limitations. A self-heating effect, for example, can't be eliminated completely via process approach. Aspects and embodiments described herein are based on a circuit approach. A perfect or near perfect response to a pulsed RF signal can be achieved with an optimized pre-heating technique, for example.

FIG. 1 depicts a power amplifier (PA) 100 having one or more amplification stages 102 configured to receive an input signal RF_IN and amplify it to generate an amplified signal RF_OUT, according to one embodiment of the present disclosure. Such a PA can include and/or be functionally coupled with a peak voltage limiting (PVL) circuit 104. Examples of such a bias circuit are described herein in greater detail.

In some embodiments, and as described herein, a bias circuit can comprise a pre-charging circuit coupled to an input port of a power amplifier and configured to generate a pre-charging bias signal for one or more amplification stages. The pre-charging bias signal can be active prior to a to-be-amplified radio frequency signal for pre-heating the one or more amplification stages.

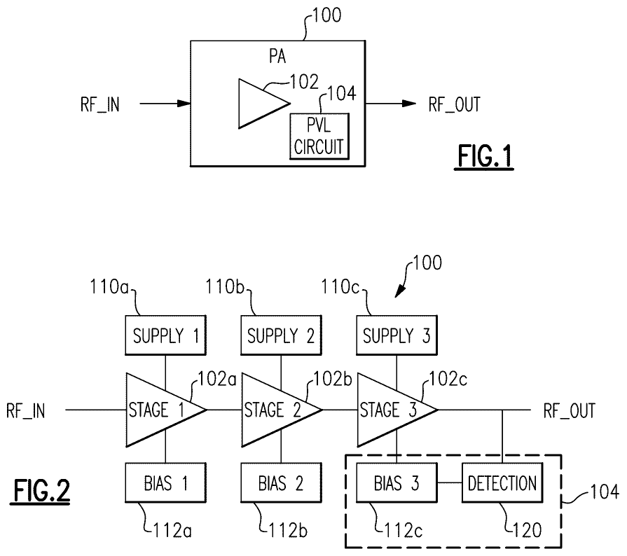

FIG. 2 shows an example of a PVL circuit 104 implemented for a PA system 100 having three amplification stages 102a to 102c, according to one embodiment of the present disclosure. An input signal RF_IN is shown to be provided to an input of the first stage 102a, and an output of the first stage 102a is shown to be provided to an input of the second stage 102b. Similarly, an output of the second stage 102b is shown to be provided to an input of the third stage 102c. An output of the third stage 102c is shown to yield an output RF_OUT of the RF system 100. Each of the three stages is shown to be coupled to a DC supply circuit (110a, 110b or 110c) and a bias circuit (112a, 112b or 112c).

In the example of FIG. 2, the PVL circuit 104 can include a detection circuit 120 that couples the output of the last stage 102c (e.g., the third stage in the three-stage example) with the bias circuit 112c for the same stage. Examples of the configuration are described herein in greater detail. It will be understood that other configurations can also be implemented. It will also be understood that although various examples are described herein in the context of three-stage PA systems, one or more features of the present disclosure can also be implemented in PA systems having different numbers of stages.

FIG. 3 shows a plot comparing a measured drain current (dashed line) to a simulated drain current (solid line) in response to the same initiating signal, according to one embodiment of the present disclosure. More specifically, the plot illustrates the drain current over a drain voltage.

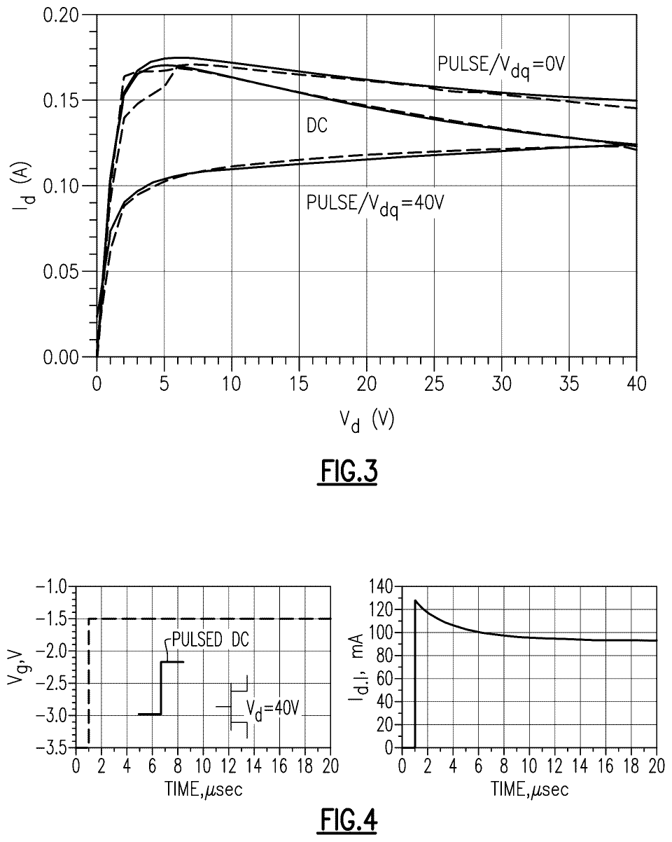

FIG. 4 shows a plot of a drain voltage response and a drain current response to a pulsed DC signal, according to one embodiment of the present disclosure.

The pulsed DC signal is exemplarily illustrated as a switch that is OFF and turned ON at a starting time of 1usec as it is illustrated in the X-axis of the plot. The switch is OFF at a gain voltage of about-3.5V and ON at a gain voltage of about-1.5V. A drain voltage of this example is about 40V.

The drain current response starts at about 130 mA when the switch is switched ON. After several microseconds in the ON-state the drain current continuously decreases to a steady-state drain current of about 90 mA to 100 mA.

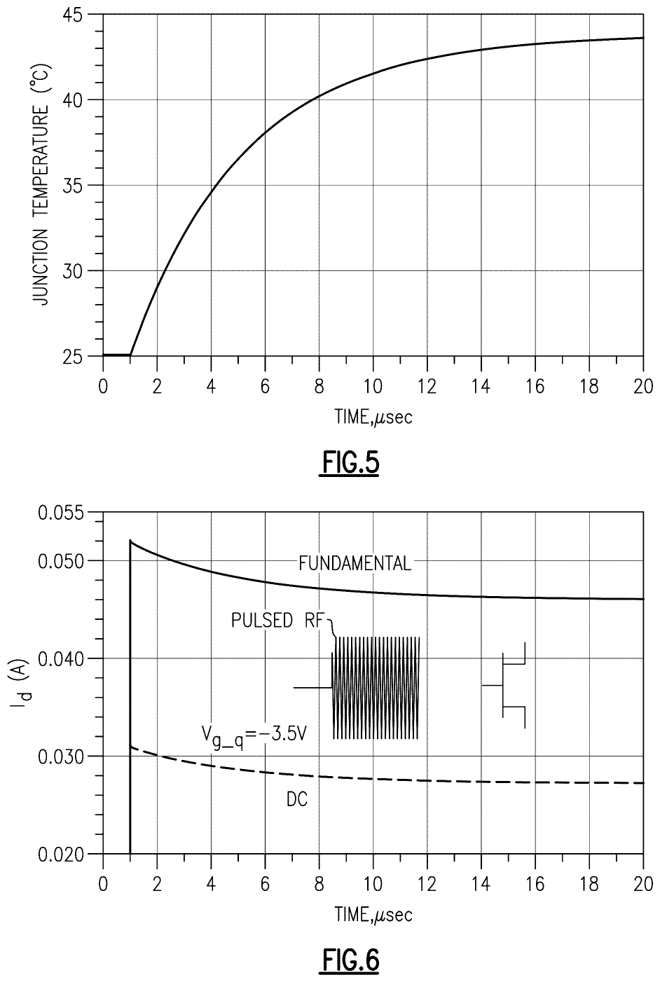

FIG. 5 shows a plot of a junction temperature response to the pulsed DC signal of FIG. 4. The junction temperature increases when the power amplifier is switched ON, in particular by the pulsed DC signal of FIG. 4. Similar to the drain current the junction temperature comes to a steady-state junction temperature after several microseconds in the ON-state. Here, the steady-state junction temperature is about 43° C., for example.

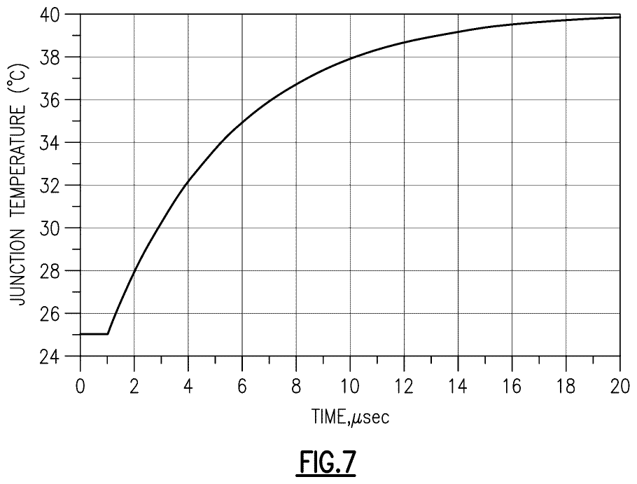

FIG. 6 shows a plot of a drain current response to a pulsed RF signal, according to one embodiment of the present disclosure.

The pulsed RF signal includes a DC response and a fundamental response. Both the DC response and the fundamental response are depicted in the plot of FIG. 6. The drain current of both the DC response and the fundamental response has a substantially similar curve compared to the drain current curve of FIG. 4. That means also the drain current response to the pulsed RF signal decreases from a starting drain current and comes to a steady-state drain current.

FIG. 7 shows a plot of a junction temperature response to the pulsed RF signal of FIG. 6. The junction temperature increases when the power amplifier is switched ON, in particular by the pulsed RF signal of FIG. 6. Similar to the drain current, the junction temperature comes to a steady-state junction temperature after several microseconds in the ON-state. Here, the steady-state junction temperature is about 40° C., for example.

Furthermore, the junction temperature response to the pulsed RF signal has the same heating gradient as the junction temperature response to the pulsed DC signal of FIG. 5. That means, the pulsed DC signal has a junction temperature response with a heating gradient that corresponds to a junction temperature response of the to-be-amplified radio frequency signal.

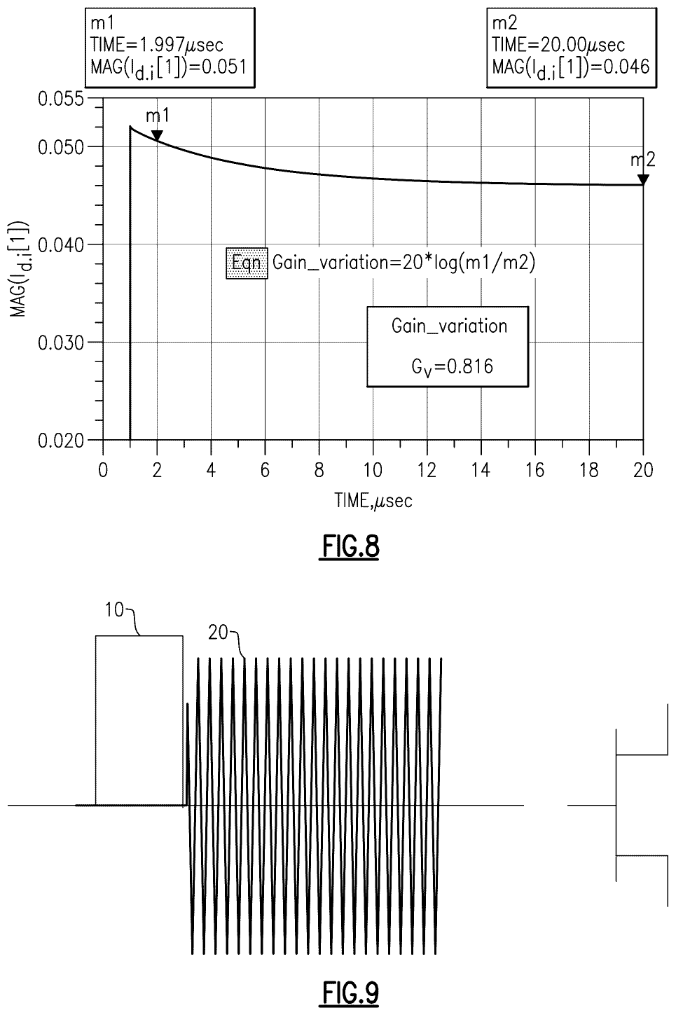

FIG. 8 shows a gain variation plot of a drain current response.

The gain variation Gv can be defined as:

$$Gain ( 1 us ) / Gain ( 1 ms ) = 20 log ( Id ( 1 us ) / Id ( 1 ms ) ) = 20 log ( 1 + deltaId / Id ) == 20 ( log e ) * deltaId / Id = 8.7 deltaId / Id$$

$$If Gain ( 1 us ) / Gain ( 1 ms ) < 0.2 dB then deltaId / Id < 2.3 \% .$$

Preferably, the gain is substantially constant. Therefore, the junction temperature needs to be substantially constant since a changing junction temperature affects the drain current and the gain.

Exemplarily, the gain variation Gv can be calculated between a first measuring point m1 at about 2 microseconds and a second measuring point m2 at about 20 microseconds. Hence, the gain variation Gv is about 0.816.

FIG. 9 schematically depicts a pre-charging bias signal 10 in relation to a to-be-amplified radio frequency signal 20, according to one embodiment of the present disclosure.

A bias circuit for a PA comprises a pre-charging circuit coupled to an input port of a PA. The pre-charging circuit is configured to generate the pre-charging bias signal 10 for one or more amplification stages. The pre-charging bias signal 10 is activated prior to the to-be-amplified radio frequency signal 20 for pre-heating the one or more amplification stages, in particular for pre-heating the PA. For example, the pre-charging bias signal 10 includes a pre-charging bias voltage or a pulsed signal or both.

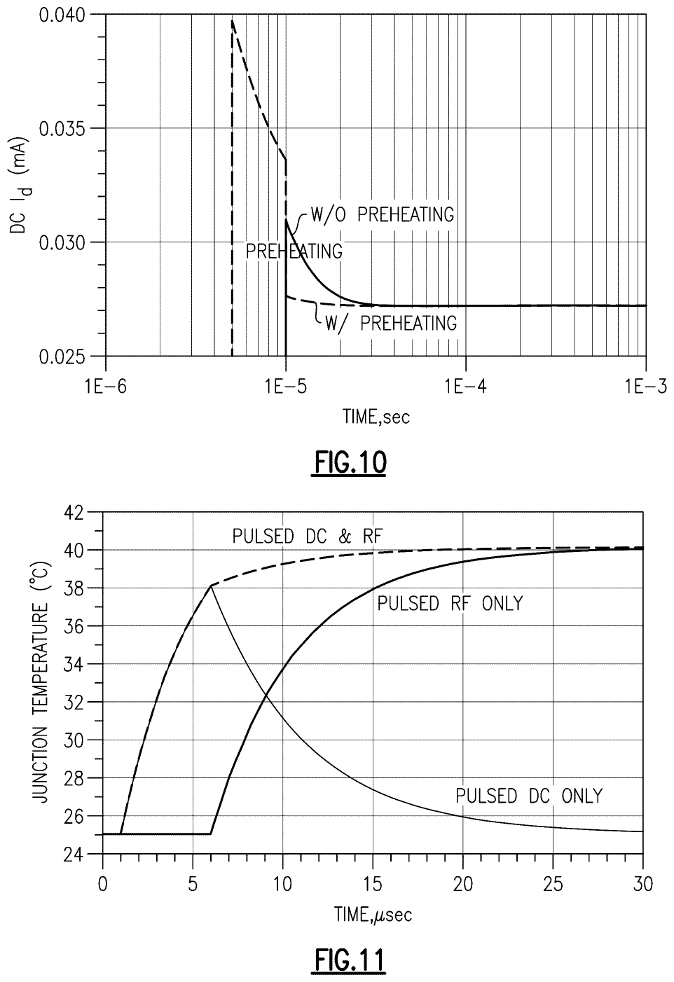

FIG. 10 shows a plot of a DC component response comparing a drain current DC Id with a pre-charging bias signal 10 and without the pre-charging bias signal, according to one embodiment of the present disclosure.

Advantageously, pre-heating is an effect of pre-charging the PA by the pre-charging bias signal 10, in particular by the pulsed DC signal.

By using the pre-charging bias signal 10 the drain current DC Id can be significantly closer to a steady-state drain current at the beginning of the to-be-amplified radio frequency signal 20 than without using the pre-charging bias signal 10.

FIG. 11 shows a plot of a junction temperature response to a pulsed DC signal and to a pulsed RF signal, according to one embodiment of the present disclosure.

Here, the pre-charging bias signal can be activated at least three microseconds prior to the to-be-amplified RF signal. In particular, the pre-charging bias signal can be activated about five microseconds prior to the to-be-amplified RF signal, as it is illustrated in FIG. 11.

For example, the pre-charging bias signal can include a pulsed DC signal. Preferably, the pulsed DC signal ends when the to-be-amplified RF signal starts.

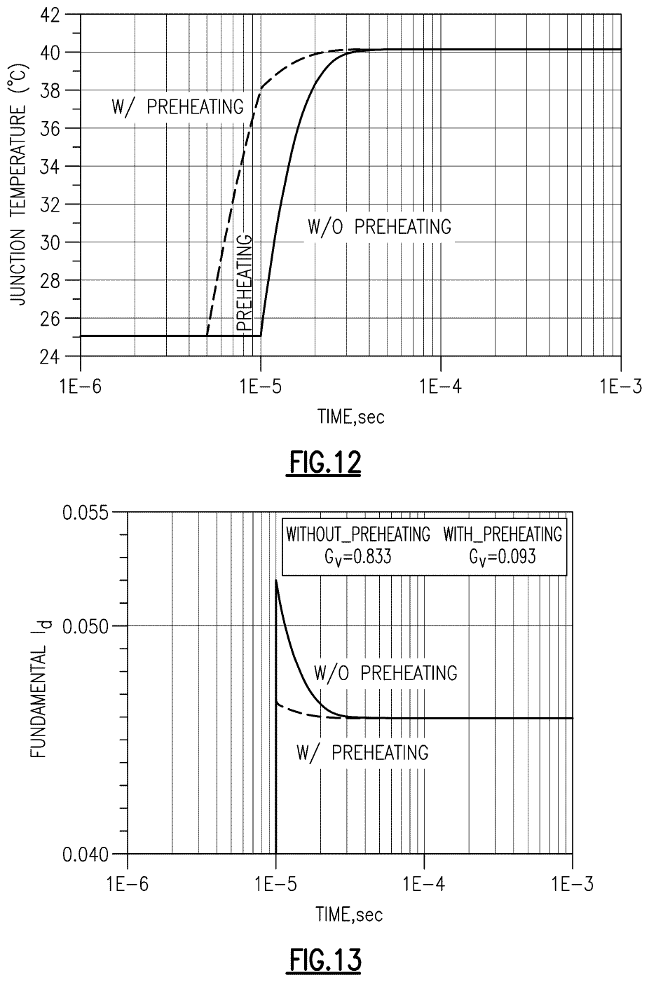

FIG. 12 shows a plot of a junction temperature response with respect to the DC component response of FIG. 10. In the plot of FIG. 12, it is emphasized that the junction temperature of the PA can be much closer to the steady-state junction temperature when pre-charged respectively pre-heated by the pre-charging bias signal. Here, the steady-state junction temperature is about 40° C. The junction temperature is pre-heated up to 38° C.

FIG. 13 shows a gain variation plot of a fundamental drain current response, according to one embodiment of the present disclosure. More specifically, the fundamental drain current response of a PA with a bias circuit according to the present disclosure is compared to the fundamental drain current response of a PA without a pre-charging bias signal. Additionally, a gain variation Gv of both PA configurations is calculated.

In some embodiments, the fundamental drain current response has a gain variation Gv of 0.10 or less. Here, the fundamental drain current response has a gain variation Gv of 0.093, for example. Hence, the gain variation Gv of the PA without the pre-charging bias signal is about ten times higher than the gain variation of the PA with the pre-charging bias signal.

As an advantage of aspects and embodiments of the present disclosure, the gain variation can be reduced significantly by the pre-charging bias signal.

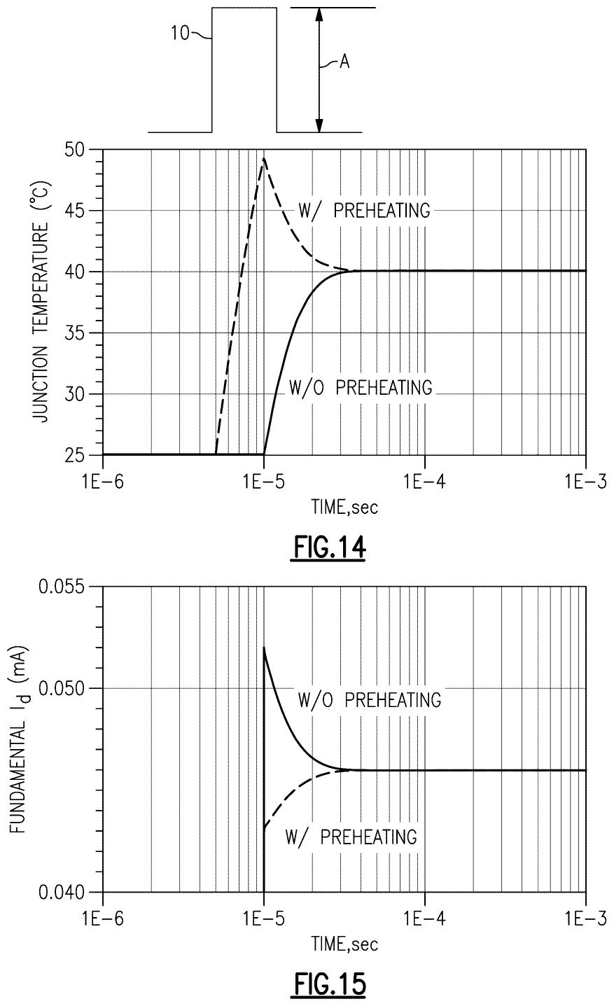

FIG. 14 shows a plot of a junction temperature response when a pre-charging bias signal has an increased amplitude A, according to one embodiment of the present disclosure. The plot of FIG. 14 substantially corresponds to the plot of FIG. 12, wherein in FIG. 14 the pre-charging bias signal 10 has a higher amplitude A.

Thus, the PA can be pre-heated above the steady-state junction temperature. The pre-heating effect can be adapted by the amplitude A of the pre-charging bias signal 10.

FIG. 15 shows a plot of a fundamental drain current with respect to the junction temperature response of FIG. 14.

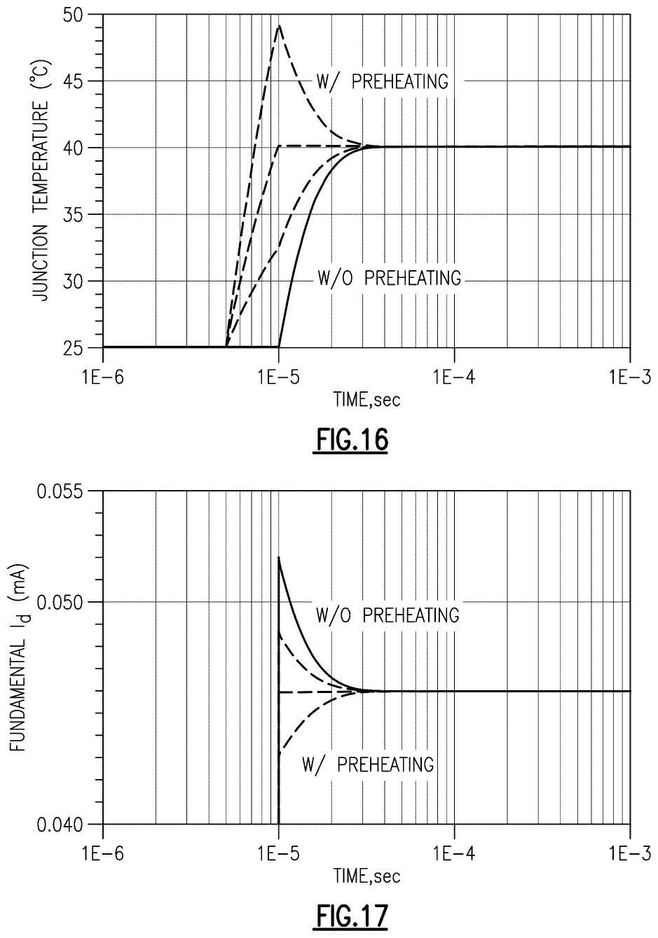

FIG. 16 shows a plot of a junction temperature response comparing pre-charging bias signals 10 (in dashed lines) having different amplitudes A, according to one embodiment of the present disclosure. For example, the junction temperature can be varied by adapting the amplitude A. Hence, the amplitude A can be increased when the pre-charging bias signal is active later or the other way round.

FIG. 17 shows a plot of a fundamental drain current with respect to the junction temperature response of FIG. 16.

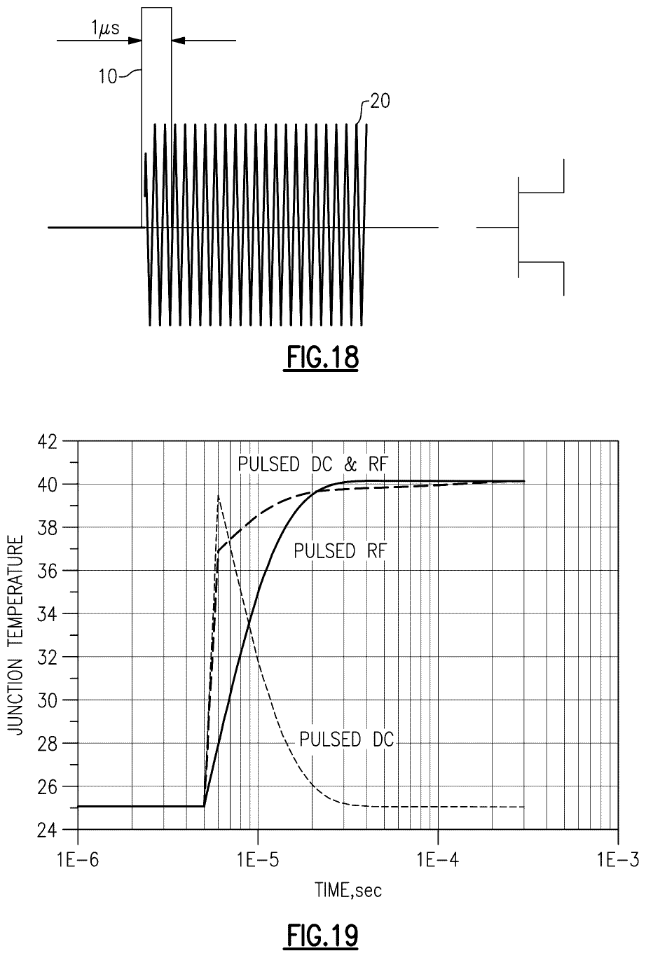

FIG. 18 schematically depicts a pre-charging bias signal 10 in relation to a to-be-amplified radio frequency signal 20 wherein the pre-charging bias signal 10 is activated when the to-be-amplified radio frequency signal 20 is activated, according to one embodiment of the present disclosure.

The pre-charging bias signal 10 can be activated before the to-be-amplified RF signal 20 is activated and keeps active when the to-be-amplified RF signal 20 is active at least for a part of the RF signal 20 duration. Alternatively, the pre-charging bias signal 10 can be activated at the same time as the to-be-amplified RF signal 20 is activated and keeps active at least for a part of the RF signal 20 duration. Thereby, the pre-charging bias signal 10 can accelerate heating up the RF device. This can also be called an enhanced heating effect. For example, the pre-charging bias signal 10 can be active for about one microsecond. The pre-charging bias signal 10 can include a pulsed DC signal.

Therefore, when pre-charging is not possible well in advance, the pre-charging bias signal 10 can be active when the to-be-amplified radio frequency signal 20 is activated, in particular the pre-charging bias signal 10 can be activated at the same time as the to-be-amplified RF signal 20 is activated.

FIG. 19 shows a plot of a junction temperature response to a pulsed DC signal and to a pulsed RF signal when activated at the same time as illustrated in FIG. 18.

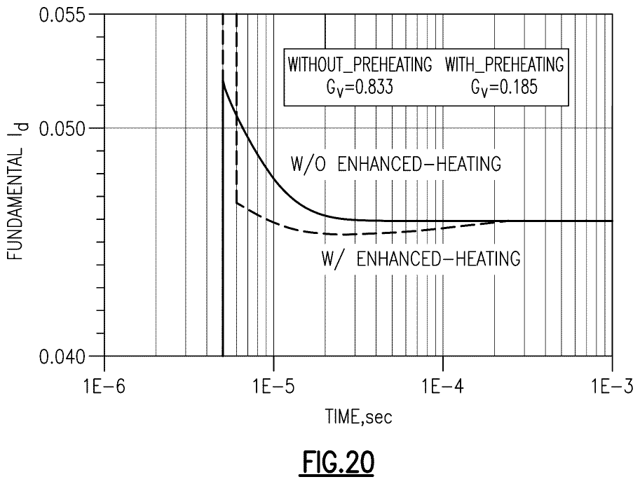

FIG. 20 shows a gain variation plot of a fundamental drain current response to the pre-charging bias signal of FIG. 18. More specifically, the fundamental drain current response of a PA with a bias circuit according to the present disclosure is compared to the fundamental drain current response of a PA without a pre-charging bias signal. Additionally, a gain variation Gv of both PA configurations is calculated.

For example, the fundamental drain current response has a gain variation Gv of 0.20 or less. Here, the fundamental drain current response has a gain variation Gv of 0.185, for example. Hence, the gain variation Gv of the PA without the pre-charging bias signal is about five times higher than the gain variation of the PA with the pre-charging bias signal.

As an advantage of the present disclosure, the gain variation can be reduced by the pre-charging bias signal also when the pre-charging bias signal 10 is activated at the same time as the to-be-amplified RF signal 20 is activated. Further, a response time of a power device comprising a bias circuit according to the present disclosure to a pulsed RF signal can be reduced.

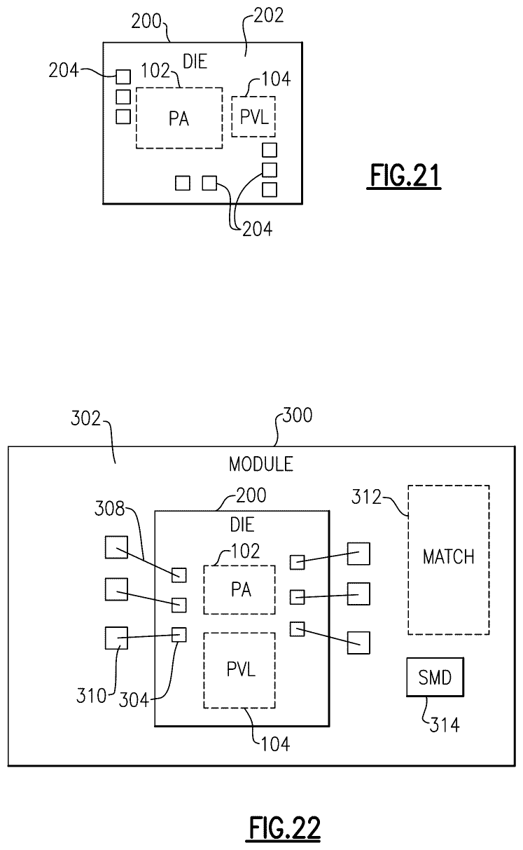

FIG. 21 depicts a die 200 that can include a bias circuit having one or more features as described herein, according to one embodiment of the present disclosure. The semiconductor die 200 can include a substrate 202 and a peak voltage limiting (PVL) circuit 104. In some embodiments, a power amplifier (PA) circuit 102 (e.g., SiGe or GaAs devices) can also be implemented on the substrate 202. A plurality of connection pads 204 can also be formed on the substrate 202 to provide, for example, power and signals for the PA circuit 102.

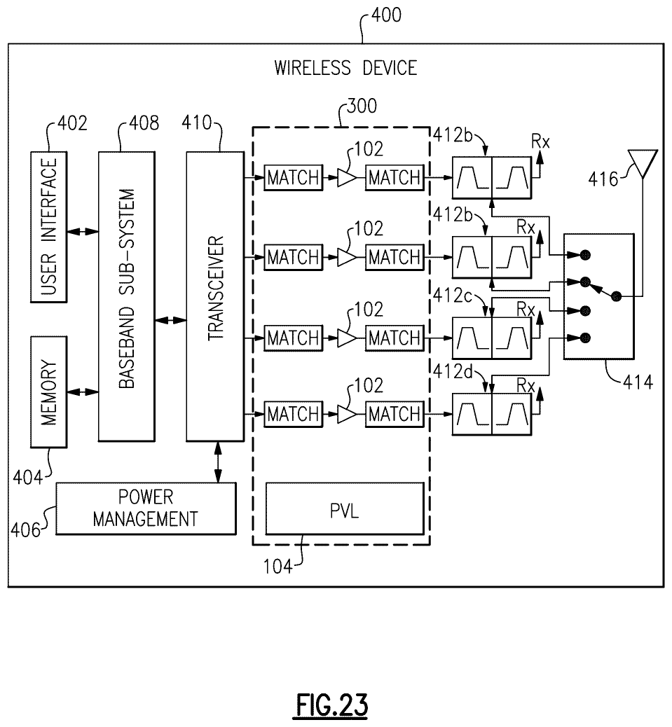

In some implementations, one or more features described herein can be included in a module. FIG. 22 schematically depicts an example module 300 having a packaging substrate 302 that is configured to receive a plurality of components, according to one embodiment of the present disclosure. In some embodiments, such components can include a die 200 having one or more featured as described herein. For example, the die 200 can include a PA circuit 102 and a PVL circuit 104. A plurality of connection pads 304 can facilitate electrical connections such as wirebonds 308 to connection pads 310 on the substrate 302 to facilitate passing of various power and signals to and from the die 200.

In some embodiments, other components can be mounted on or formed on the packaging substrate 302. For example, one or more surface mount devices (SMDs) (314) and one or more matching networks (322) can be implemented. In some embodiments, the packaging substrate 302 can include a laminate substrate.

In some embodiments, the module 300 can also include one or more packaging structures to, for example, provide protection and facilitate easier handling of the module 300. Such a packaging structure can include an overmold formed over the packaging substrate 302 and dimensioned to substantially encapsulate the various circuits and components thereon.

It will be understood that although the module 300 is described in the context of wirebond-based electrical connections, one or more features of the present disclosure can also be implemented in other packaging configurations, including flip-chip configurations.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc.

FIG. 23 schematically depicts an example wireless device 400 having one or more advantageous features described herein, according to one embodiment of the present disclosure. One or more PAs 102 as described herein can utilize one or more PVL circuits 104 as described herein. In embodiments where the PAs 102 and their PVL circuit(s) 104 are packaged into a module, such a module can be represented by a dashed box 300. In some embodiments, the module 300 can include at least some of input and output matching circuits.

The PAs 102 can receive their respective RF signals from a transceiver 410 that can be configured and operated in a known manner to generate RF signals to be amplified and transmitted, and to process received signals. The transceiver 410 is shown to interact with a baseband sub-system 408 that is configured to provide conversion between data and/or voice signals suitable for a user and RF signals suitable for the transceiver 410. The transceiver 410 is also shown to be connected to a power management component 406 that is configured to manage power for the operation of the wireless device 400. Such power management can also control operations of the baseband sub-system 408 and the module 300.

The baseband sub-system 408 is shown to be connected to a user interface 402 to facilitate various input and output of voice and/or data provided to and received from the user. The baseband sub-system 408 can also be connected to a memory 404 that is configured to store data and/or instructions to facilitate the operation of the wireless device, and/or to provide storage of information for the user.

In the example wireless device 400, outputs of the PAs 102 are shown to be matched and routed to an antenna 416 via their respective duplexers 412a-412d and a band-selection switch 414. The band-selection switch 414 can be configured to allow selection of, for example, an operating band or an operating mode. In some embodiments, each duplexer 412 can allow transmit and receive operations to be performed simultaneously using a common antenna (e.g., 416). In FIG. 23, received signals are shown to be routed to “Rx” paths (not shown) that can include, for example, a low-noise amplifier (LNA).A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While its specific embodiments of and examples for the invention are described above for illustrative purposes, various equivalent modifications are possible within the scope of the invention, as those skilled in the relevant art will recognize. For example, while processes or blocks are presented in a given order, alternative embodiments may perform routine and may employ systems having blocks, in a different order, or some processes or blocks may be deleted, moved, added, subdivided, combined and/or modified. Each of these blocks may be implemented in a variety of different ways.

The teaching of the present invention provided herein can be applied to other systems, not necessarily the system described above. The elements and various embodiments described above can be combined to provide further embodiments.

While certain embodiments of the present invention have been described, these embodiments have been presented by way of example only, and are not intended to limit the scope of the disclosure. Indeed, the device and system described herein may be embodied in a variety of other forms. Furthermore, various omissions, substitutions and changes in the form of the system described herein may be made without departing from the spirit of the disclosure. The accompanying claims and the equivalents are intended to cover such forms or modifications as would fall within the scope and spirit of the disclosure.

1. A bias circuit for a power amplifier, comprising:
a pre-charging circuit coupled to an input port of a power amplifier and configured to generate a pre-charging bias signal for one or more amplification stages, the pre-charging bias signal being active prior to a to-be-amplified radio frequency signal for pre-heating the one or more amplification stages.

2. The bias circuit of claim 1 wherein the pre-charging bias signal includes a pre-charging bias voltage.

3. The bias circuit of claim 1 wherein the pre-charging bias signal includes a pulsed signal.

4. The bias circuit of claim 1 wherein the pre-charging bias signal includes a pulsed DC signal.

5. The bias circuit of claim 4 wherein the pulsed DC signal has a junction temperature response with a heating gradient that corresponds to a junction temperature response of the to-be-amplified radio frequency signal.

6. The bias circuit of claim 1 wherein the pre-charging bias signal is active at least three microseconds prior to the to-be-amplified radio frequency signal.

7. The bias circuit of claim 1 wherein the pre-charging bias signal is active at least five microseconds prior to the to-be-amplified radio frequency signal.

8. The bias circuit of claim 1 wherein the pre-charging bias signal is active at substantially a same time as the to-be-amplified radio frequency signal.

9. The bias circuit of claim 1 wherein a response signal has a drain current, the drain current having a gain variation of 0.10 or less.

10. A power amplifier (PA) comprising:
an input port configured to receive an input radio frequency (RF) signal;
an output port configured to output an amplified RF signal;
one or more amplification stages implemented between the input port and the output port, the one or more amplification stages configured to amplify the input RF signal to yield the amplified RF signal; and
one or more bias circuits, each bias circuit including a pre-charging circuit coupled to the input port and configured to generate a pre-charging bias signal for the one or more amplification stages, the pre-charging bias signal being active prior to the input RF signal for pre-heating the one or more amplification stages.

11. The power amplifier of claim 10 wherein the pre-charging bias signal includes a pre-charging bias voltage.

12. The power amplifier of claim 10 wherein the pre-charging bias signal includes a pulsed signal.

13. The power amplifier of claim 10 wherein the pre-charging bias signal includes a pulsed DC signal.

14. The power amplifier of claim 13 wherein the pulsed DC signal has a junction temperature response with a heating gradient that corresponds to a junction temperature response of the to-be-amplified radio frequency signal.

15. The power amplifier of claim 10 wherein the pre-charging bias signal is active at least three microseconds prior to the to-be-amplified radio frequency signal.

16. The power amplifier of claim 10 wherein the pre-charging bias signal is active at least five microseconds prior to the to-be-amplified radio frequency signal.

17. The power amplifier of claim 10 wherein the pre-charging bias signal is active at substantially a same time as the to-be-amplified radio frequency signal.

18. The power amplifier of claim 10 wherein a response signal has a drain current, the drain current having a gain variation of 0.10 or less.

19. A wireless device comprising:
a transceiver configured to generate a radio frequency (RF) signal;
a radio frequency (RF) module in communication with the transceiver, the RF module including a power amplifier (PA), the PA including one or more amplification stages configured to amplify the RF signal, the PA further including a bias circuit for each of the one or more amplification stages, the bias circuit including a pre-charging circuit coupled to an input port of the PA and configured to generate a pre-charging bias signal for the one or more amplification stages, the pre-charging bias signal being active prior to the RF signal for pre-heating the one or more amplification stages; and
an antenna in communication with the RF module, the antenna configured to facilitate transmission of the amplified RF signal.
